(19) United States
(12) Patent Application Publication
(10) Pub. No.: US 2008/0047133 A1
(43) Pub. Date: Feb. 28, 2008

(54) MANUFACTURING PROCESS AND END PRODUCT OF A WIRE-LIKE STRIP

(75) Inventor: Rogerio Scheffer, Parana (BR)

Correspondence Address: FURR LAW FIRM, 2622 DEBOLT ROAD, UTICA, OH, 43080, US

(73) Assignee: AGAIA SISTEMAS DE ARNAZENEGEM S/A, Parana (BR)

(21) Appl. No.: 11/467,561

(22) Filed: Aug. 27, 2006

(51) Int. Cl. H01L 39/24

(52) U.S. Cl. 29/825; 29/599

(57) ABSTRACT

“MANUFACTURING PROCESS AND END PRODUCT OF A WIRE-LIKE STRIP”, described as a manufacturing process and end product of a wire-like strip which, according to the characteristics thereof, provides the formation of a specific and proprietary manufacturing process for producing wire-like strips (1) specifically for the utilization in metallic wire cloths for trays, containers, partitions, fences, cable ditches and similar items and having as a basis a fully acceptable substituting alternative for the wire raw material, possessing a high initial manufacturing cost, which is the utilization of flat steel strips (2) such as carbon steel plate strips extracted from steel coils after a longitudinal cutting process (Slitter cutting) by means of a complete and sequential recoiling, straightening and shaping process thereof, so as to obtain a wire-like strip (1) straightened and welded to form a rectangular section.

The present patent relates to mechanical processes and products for the manufacturing of strips in general, more specifically to a manufacturing process and end product of a wire-like strip which, according to the general characteristics thereof, possesses as a basic principle to provide the formation of a specific and proprietary manufacturing process for producing a wire-like strip specific for the utilization in metallic wire cloths for trays, containers, partitions, fences, cable ditches and similar items, by replacing a basic product for another one resulting in extraordinary improvements in performance and economy for the most varied purposes it is intended for, that is, the generation of a system for reusing strips resulting from the longitudinal cutting process (Slitter cutting) and having as a basis a strip of great resistance, strength, and versatility. With specific design and shape, easily accessible for a better adaptation and safety for the users, specific process, practical handling, functionality, accessible cost and due to its general characteristics, is easily adaptable to the most varied types of wire cloths for manufacturing trays, containers, partitions, fences, cable ditches and similar items in general, regardless of the characteristics thereof.

The patent in question is characterized in that it aggregates components and processes in a differentiated concept to meet the several requirements the nature of its use demands, that is, the manufacturing of wire cloths for the most varied purposes. Such concept provides an end product having more efficiency, functionality, resistance, safety, accuracy, versatility and mainly economy, due to its excellent technical qualities, thereby providing advantages and improvements in the manufacturing of the most varied types of metallic wire cloths as a whole, the general characteristics of which differ from the other shapes and models known in the current state of the art.

The manufacturing processes of metallic wire cloths directly used in the production of containers, trays, partitions and similar items and widely known in the current state of the art are based on the utilization of low carbon wires of different gauges and on the welding of wires with meshes of different spaces, the wire raw material being originally produced by steelworks specialized in this type of material, with a subsequent process to mechanically reduce the wire diameter (wire drawing) so as to achieve the desired diameters for each one of the types of applications it is intended for, that is, they vary according to use, load capacity or manufacturing process.

The general conception of the present manufacturing process and end product of a wire-like strip is based on a fully acceptable substituting alternative for the wire raw material, which possesses a high initial manufacturing cost and greatly burdens the entire productive chain and, consequently, the end product, particularly due to the few number of such companies in the market which thus helps keeping the high prices. The substituting alternative is based on the utilization of carbon steel plate strips directly extracted from steel coils (flat steel sheet original shape in the steelworks) after the longitudinal cutting process (Slitter cutting), whose scrap has no further use except for the foundry process and, as a scrap, that is, a disposable material, the initial value thereof is extremely low and, consequently, can greatly benefit several industrial processes with the purpose of being transformed again into a fully reusable product; a process and products that would, therefore, possess dramatically lower costs.

The present patent consists in the utilization of a modern, practical and efficient manufacturing process and end product of a wire-like strip formed by an assembly of properly incorporated mechanical and manufacturing solutions comprising a complete and differentiated wire-like strip, with an exclusive design, optimum finish details and proprietary characteristics, incorporating a strip straightened and welded to form a rectangular section and obtained from a complete and sequential recoiling, straightening and continuous welding process of flat steel parings such as carbon steel plate strips extracted from steel coils (flat steel sheet original shape in the steelworks) after the longitudinal cutting process (Slitter cutting) so as to provide the formation of a unique, complete and safe product whose shapes and internal and external arrangements are generated from two strips longitudinally and continuously welded to form a single body thus changing its shape to something similar to a wire since the section thickness and width are the same size and similar to that of a rectangle.

The present manufacturing process and end product of a wire-like strip is based on the application of components and processes in a differentiated concept and employed in the manufacturing of wires and similar items in general for the application in wire cloths for trays, containers, partitions, fences, cable ditches and similar items, without, however, achieving a high degree of sophistication and complexity, thereby allowing to solve some of the main inconvenience of the other shapes and models in the current state of the art, which are located in a work range wherein the shapes and/or models have a fairly high cost and general heavy weight, are difficult and slow to install and require high skilled labor.

### SUMMARY

The “MANUFACTURING PROCESS AND END PRODUCT OF A WIRE-LIKE STRIP”, described as a manufacturing process and end product of a wire-like strip which, according to the characteristics thereof, provides the formation of a specific and proprietary manufacturing process for producing wire-like strips (1) specifically for the utilization in metallic wire cloths for trays, containers, partitions, fences, cable ditches and similar items and having as a basis a fully acceptable substituting alternative for the wire raw material, possessing a high initial manufacturing cost, which is the utilization of flat steel strips (2) such as carbon steel plate strips extracted from steel coils after a longitudinal cutting process (Slitter cutting) by means of a complete and sequential recoiling, straightening and shaping process thereof, so as to obtain a wire-like strip (1) straightened and welded to form a rectangular section.

### BRIEF DESCRIPTION OF DRAWINGS

The objects, advantages and other important characteristics of the patent in question can be more easily understood when read jointly with the appended drawings, wherein:

FIG. 1 is a frontal perspective view of the end product of a wire-like strip.

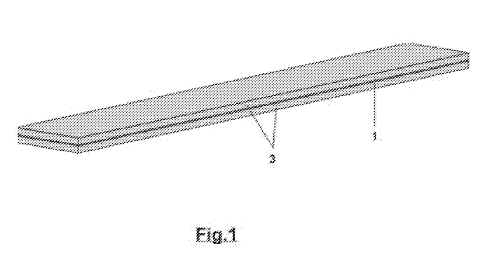

FIG. 2A is a schematic view of the manufacturing process and end product of a wire-like strip showing the manufacturing process during the recoiling stage.

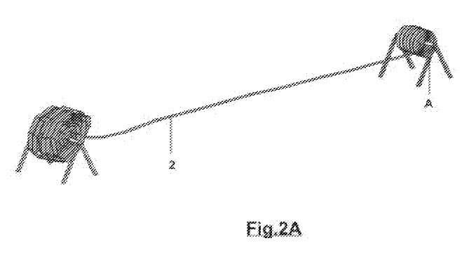

FIG. 2B is a schematic view of the manufacturing process and end product of a wire-like strip showing the manufacturing process during the straightening stage.

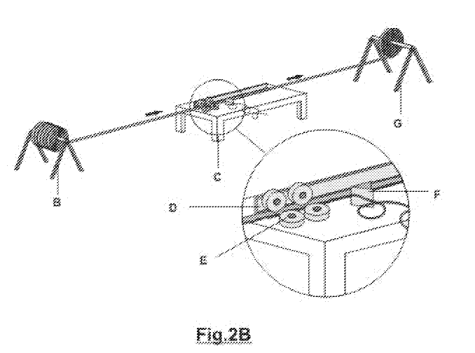

FIG. 2C is a schematic view of the manufacturing process and end product of a wire-like strip showing the manufacturing process during the continuous welding, straightening and cutting stages.

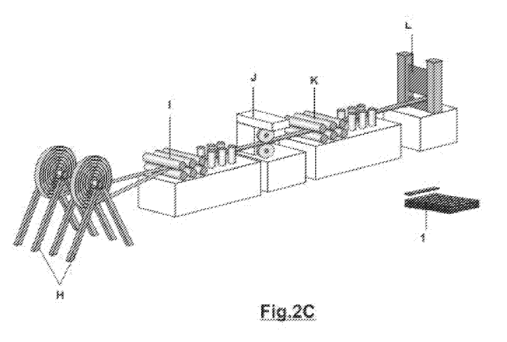

### DETAILED DESCRIPTION

As can be inferred from the appended drawings that illustrate and integrate the present descriptive report of the patent of invention “Manufacturing Process and End Product of a Wire-like Strip”, the same comprises a wire-like strip (1) straightened and welded to form a rectangular section and obtained from a complete and sequential recoiling, straightening and continuous welding process of flat steel strips (2) such as carbon steel plate strips extracted from steel coils (flat steel sheet original shape in the steelworks) after the longitudinal cutting process (Slitter cutting) so as to form and end product whose shapes and internal and external arrangements are generated from two of these flat steel strips (2) longitudinally and continuously welded to form a single and uniform body thus changing its shape to something similar to a wire since the section thickness and width are the same size and similar to that of a rectangle whose sides are very close in size.

The manufacturing process is based on three fully mechanized stages schematically arranged in a well-defined and consecutive manner, the first stage being that of the recoiling phase, the second stage being that of the straightening phase and the third, the continuous welding phase with later straightening and cutting of the flat steel strips (2).

The recoiling stage, as shown on FIG. (2A), is made up by a fully organized recoiling process of the roller of flat steel strips (2) along with carbon steel plate strips (scrap from the flat steel sheet longitudinal cutting) which are initially rolled into a fully disorganized and uncertain way in a mechanical recoiler (A), so as to transform the roller of flat steel strips (2) into coils with specific width and diameter.

In the straightening stage, as shown on FIG. (2B), the flat steel strips (2) are rolled in a mechanical uncoiler (B), so as to start straightening the material on its width. Next, the flat steel strips (2) go to a liner device (C) that guides them by their inner side and in a fully rectilinear way through a groove (D), an assembly of lateral horizontal and vertical rollers (E) arranged above and laterally adjacent to the flat steel strips (2) in order to position them inside the groove (D) square and a set of knives (F) contacting the flat steel strips (2) free side with the purpose of cutting and extracting excess material from the flat steel strips (2) width and, consequently, straighten them and transform them into standardized material. Finally, the flat steel strips (2) go through a recoiler (G) thereby concluding the straightening process and forming a strip coil with an adjusted width.

The continuous welding stage, as shown on FIG. (2C), is carried out by positioning the two coils of flat steel strips (2) straightened and symmetrical on their width in mechanical uncoilers (H) to start the continuous welding process of the material to produce the end product. Next, the two flat steel strips (2) are rolled into an assembly of vertical side rollers (I) to be fully pressed in an overlapped position and vertically and laterally aligned with each other. Next, the flat steel strips (2) are guided to the continuous welding device (J) made up by two copper discs, which are conductors of electric current generated by a direct current transformer and are vertically aligned to conduct current at the welding point, where they pass through aligned and overlapped between the two discs and are continuously welded with each other by their inner faces to produce a single body of the wire-like strip (1). Then, the wire-like strip (1) is guided to an assembly of horizontal and vertical straightening rollers (K) positioned in such a way as to straighten and eliminate wrinkles thereof, obtained during the straightening and continuous welding processes. Finally, the wire-like strip goes through a pneumatic cutting device (L) in which a sensor determines the desired length and activates the cutting element.

One of the great advantages of the end product of a wire-like strip is the wide possibility of being manufactured in different sizes, both in width and thickness, for it can be positioned in such a way to better use its strength, increasing the section inertia with an improved performance as related to resistance and, especially, buckling strength, that is, the larger side is always placed in an upright position so that the height of the wire-like strip (1) is increased, i.e., being the section rectangular dramatically favors its application in situations where some size characteristics proper to rectangular sections are required, since the strips can be positioned with their large size in the direction of the load drive, resulting thereby in greater resistance with less material.

One of the great advantages of the manufacturing process is that the energy employed is reusable and does not emit pollutant gases as it happens in the foundry process, which would probably be the most acceptable alternative for using the scrap from carbon steel plate strips directly extracted from the longitudinal cutting process (Slitter cutting) of steel coils (flat steel sheet original shape in the steelworks). It is, therefore, a process that brings important environmental benefits by the immediate material recycling process and no damage to the environment.

As its structures are made of strong metallic material or similar material with equal or higher lightness and strength, the end product of a wire-like strip has a high level of durability and strength, provides great safety for the users and, when used in the most varied types of wire cloths for trays, containers, partitions, fences, cable ditches and similar items, does not present any risks of fatigue.

For all of the above, this is a process and a product that will be well received by the companies manufacturing trays, containers, partitions, fences, cable ditches and similar items based on wires, since the present manufacturing process and end product of a wire-like strip presents several advantages, such as: great safety, reliability and agility in its application; extremely high mechanical resistance and durability, low or no wear of the assembly as a whole; great efficiency and performance in its application due to its general conception; greater comfort and safety to the users in general; low weight and density; practical and safe use by any user; fully accessible costs which provides an optimum cost/benefit ratio; simplified manufacturing; greater general load capacity; a large variety of materials employed in the manufacture; great versatility and flexibility provided by the several types of application; all the production stages are easy and fast; ecological, since it reuses disposable material, saves energy and reduces the emission of pollutant gases; and the certainty of always having a process and, especially, a product that fully meets the safety, resistance and strength conditions required to its application.

For all of the above, the manufacturing process and end product of a wire-like strip can be classified as a fully efficient, accurate and safe means for the manufacturing, in an extremely practical and economic way, of wire-like strips (1) of different gauges from flat steel strips (2) and for the application in the most varied types of wire cloths for trays, containers, partitions, fences, cable ditches and similar items, regardless of the general characteristics thereof; they are also easy to produce, to install and to handle and have great strength and excellent characteristics; the sizes, dimensions and quantities may vary, depending on the use needs.

I claim:

1. A “MANUFACTURING PROCESS AND END PRODUCT OF A WIRE-LIKE STRIP”, comprising a wire-like strip (1) straightened and welded to form a rectangular section and obtained from a complete and sequential recoiling, straightening and continuous welding process of flat steel strips (2) such as carbon steel plate strips extracted from steel coils (flat steel sheet original shape in the steelworks) after the longitudinal cutting process (Slitter cutting) so as to form an end product whose shapes and internal and external arrangements are generated from two of these flat steel strips (2) longitudinally and continuously welded to form a single and uniform body thus changing its shape to something similar to a wire since the section thickness and width are the same size and similar to that of a rectangle whose sides are very close in size.

2. A “MANUFACTURING PROCESS AND END PRODUCT OF A WIRE-LIKE STRIP”, according to claim 1 further comprising a recoiling stage made up by a fully organized recoiling of the roller of flat steel strips (2) such as carbon steel plate strips (scrap from the flat steel sheet longitudinal cutting) into a mechanical uncoiler (A) to transform the roller of flat steel strips (2) into coils with specific width and diameter; a straightening stage made up by positioning the steel coils (2) in a mechanical uncoiler (B); next, the flat steel strips (2) go to a liner device (C) that guides them by their inner side and in a fully rectilinear way through a groove (D), an assembly of lateral horizontal and vertical rollers (E) arranged above and laterally adjacent to the flat steel strips (2) in order to position them inside the groove (D) square and a set of knives (F) contacting the flat steel strips (2) free side with the purpose of cutting and extracting excess material from the flat steel strips (2) width and, consequently, straighten them and transform them into standardized material; and finally, the flat steel strips (2) go through a recoiler (G) thereby concluding the straightening process and forming a strip coil with an adjusted width; and a continuous welding stage made up by positioning two coils of flat steel strips (2) straightened and symmetrical on their width in mechanical uncoilers (H); then, the two flat steel strips (2) are rolled into an assembly of vertical side rollers (I) to be fully pressed in an overlapped position and vertically and laterally aligned with each other; next, the flat steel strips (2) are guided to the continuous welding device (J) made up by two copper discs, which are conductors of electric current generated by a direct current transformer and are vertically aligned to conduct current at the welding point, where they pass through aligned and overlapped between the two discs and are continuously welded with each other by their inner faces to produce a single body of the wire-like strip (1); then, the wire-like strip (1) is guided to an assembly of horizontal and vertical straightening rollers (K) positioned in a such a way as to straighten and eliminate wrinkles thereof; and, finally, the wire-like strip (1) goes through a pneumatic cutting device (L) in which a sensor determines the desired length and activates the cutting element.
